(19) United States
(12) Patent Application Publication
(10) Pub. No.: US 2026/0361303 A1
(43) Pub. Date: Nov. 12, 2026

(54) INTEGRATED CIRCUIT FOR DIFFERENTIAL LINE DRIVER

(71) Applicant: Analog Bits Inc., Sunnyvale, CA (US)

(72) Inventor: Michael A. Ang, San Francisco, CA (US)

(21) Appl. No.: 19/451,754

(22) Filed: Jan. 16, 2026

Related U.S. Application Data
(60) Provisional application No. 63/746,483, filed on Jan. 17, 2025.

(51) Int. Cl. H03K 17/687; G05F 1/56

(52) U.S. Cl. CPC H03K 17/687; G05F 1/56

(57) ABSTRACT

An integrated circuit includes first and second voltage supplies respectively providing a first voltage rail and a second voltage rail, a first differential circuit driven by the first voltage rail and having a first push-pull portion and a second push-pull portion, a second differential circuit driven by the second voltage rail and having a first pull-up portion and a second pull-up portion coupled by a switch. The first push-pull portion is coupled to the first pull-up portion. The second push-pull portion is coupled to the second pull-up portion. Each push-pull portion has a pull-up circuit receiving a component of a first data signal and a pull-down circuit receiving a component of a second data signal. The first and second pull-up portions are configured to receive the corresponding component of the first data signal. The two differential circuits jointly output a differential output signal.

### CROSS-REFERENCE TO RELATED APPLICATION

This application claims priority to U.S. Provisional Patent Application No. 63/746,483, filed on Jan. 17, 2025, the entire disclosure of which is incorporated by reference.

### TECHNICAL FIELD

The disclosure generally relates to integrated circuits (ICs) for differential line drivers.

### BACKGROUND

A differential line driver is an example of a mixed-signal circuit that has seen wide applications in communication and signal processing devices. An application can include two types of differential line drivers, namely, voltage mode drivers and current mode drivers. Voltage mode drivers usually provide good power efficiency and ease of digital implementation but have limited output amplitude. In contrast, current mode drivers usually provide higher output amplitude but with lower power efficiency and more complex design considerations, e.g., analog headroom for keeping field-effect transistor (FET) current sources in saturation mode.

Each of the types of differential line drivers can provide for advantages or disadvantages in terms of area, power, performance, or complexity of the mixed-signal circuit. That is, each of types of differential line drivers allows for different levels of control and configurability of the circuit pertaining to output impedance, output amplitude, output common mode voltage, output equalization, or a combination thereof.

### SUMMARY

This specification describes an integrated circuit that is configured to include an modular/array-based segmented differential line driver. In particular, the line driver includes a pullup-only current-mode driver portion powered by a higher voltage to scale up the amplitude of a push-pull voltage-mode driver portion powered by a lower voltage.

The integrated circuit can include a first voltage supply configured to provide a first voltage rail; a second voltage supply configured to provide a second voltage rail higher than the first voltage rail; a first differential circuit coupled to the first voltage supply and driven by the first voltage rail, the first differential circuit comprising a first push-pull portion and a second push-pull portion; and a second differential circuit coupled to the second voltage supply and driven by the second voltage rail, the second differential circuit comprising a first pull-up portion and a second pull-up portion coupled to each other by a switch controlled by a control signal.

The first push-pull portion can be coupled to the first pull-up portion through a first resistor, and the second push-pull portion can be coupled to the second pull-up portion through a second resistor, where each of the first push-pull portion and the second push-pull portion includes a pull-up circuit coupled to the first voltage supply and configured to receive one of a first component and a second component of a first data signal; and a pull-down circuit coupled to a third voltage supply and configured to receive one of a first component and a second component of a second data signal, where the first pull-up portion is configured to receive the first component of the first data signal, and the second pull-up portion is configured to receive the second component of the first data signal, and where the first differential circuit and the second differential circuit jointly generate a differential output signal.

In some implementations, the pull-up circuit of the first push-pull portion and the pull-up circuit of the second push-pull portion each comprise at least one first p-type metal-oxide-semiconductor (PMOS) transistor of the pull-up circuit having a gate terminal configured to receive one component of the first data signal.

In some implementations, the pull-down circuit of the first push-pull portion and the pull-down circuit of the second push-pull portion each comprise at least one n-type metal-oxide-semiconductor (NMOS) transistor of the pull-down circuit configured to receive one component of the second data signal.

In some implementations, the first pull-up portion and the second pull-up portion each comprise a first PMOS transistor of the pull-up portion, and a second PMOS transistor of the pull-up portion, wherein a gate terminal of the first PMOS transistor of the first pull-up portion and a gate terminal of the first PMOS transistor of the second pull-up portion are both coupled to a bias voltage to form one or more current sources.

In some implementations, the first pull-up portion and the second pull-up portion each comprise a second PMOS transistor, where a gate terminal of the second PMOS transistor of the first pull-up portion and a gate terminal of the second PMOS transistor of the second pull-up portion are respectively coupled to one of the first and second components of the first data signal.

In some implementations, a drain terminal of the second PMOS transistor of the first pull-up portion and a drain terminal of the second PMOS transistor of the second pull-up portion are jointly coupled to a differential output port that outputs the differential output signal.

In some implementations, the at least one first PMOS transistor includes multiple first PMOS transistors having a gate terminal coupled to the third voltage supply. In some implementations, the at least one NMOS transistor comprises a plurality of NMOS transistors having a gate terminal that is coupled to the first voltage supply.

In some implementations, the switch includes a transistor having a gate terminal configured to receive the control signal.

In some implementations, the integrated circuit is configured to operate in one of: a first mode, a second mode, a third mode, and a fourth mode. In this case, when the integrated circuit operates in the first mode, the integrated circuit converts the first and the second components of the first data signal both to logic 1, converts the first and the second components of the second data signal both to logic 0, and sets an incremental current to zero to turn off amplitude scaling. Additionally, when the integrated circuit operates in the second mode, the integrated circuit converts the first and the second components of the first data signal both to logic 1, converts the first and the second components of the second data signal both to logic 1, and sets the incremental current to zero to turn off amplitude scaling. Additionally, when the integrated circuit operates in the third mode, the integrated circuit converts the first components of the first and second data signals to first digital counterparts, converts the second components of the first and second data signals to second digital counterparts, sets the control signal to logic 0, and sets an incremental current at 0.5 times a bias current to turn on amplitude scaling, wherein the second digital counterparts are complements of the first digital counterparts. Additionally, when the integrated circuit operates in the fourth mode, the integrated circuit converts the first and the second components of the first data signal both to logic 0, converts the first and the second components of the second data signal both to logic 0, sets the control signal to logic 1, and sets the incremental current to equal the bias current to turn on amplitude scaling.

In some implementations, the incremental current is adjusted according to an incremental differential voltage of the differential output signal.

In some implementations, the first differential circuit comprises a plurality of thin oxide transistors, and the second differential circuit comprises a plurality of thick oxide transistors.

For another integrated circuit, the integrated circuit includes a plurality of driver circuits; a first voltage supply configured to provide a first voltage rail; a second voltage supply configured to provide a second voltage rail higher than the first voltage rail; a differential output port coupled to the plurality of driver circuits; a control port configured to provide a plurality of control signals to the plurality of driver circuits, respectively; a first differential input port configured to provide a plurality of first differential input signals to the plurality of driver circuits, respectively; a second differential input port configured to provide a plurality of second differential input signals to the plurality of driver circuits, respectively; where each driver circuit of the plurality of driver circuits includes a first differential circuit coupled to the first voltage supply and driven by the first voltage rail, the first differential circuit comprising a first push-pull portion and a second push-pull portion; and a second differential circuit coupled to the second voltage supply and driven by the second voltage rail, the second differential circuit comprising a first pull-up portion and a second pull-up portion coupled to each other by a switch controlled by a control signal, where the first push-pull portion is coupled to the first pull-up portion through a first resistor, and the second push-pull portion is coupled to the second pull-up portion through a second resistor, where each of the first push-pull portion and the second push-pull portion comprises: a pull-up circuit coupled to the first voltage supply and configured to receive one of a first component and a second component of a first data signal; and a pull-down circuit coupled a third voltage supply and configured to receive one of a first component and a second component of a second data signal, where the first pull-up portion is configured to receive the first component of the first data signal, and the second pull-up portion is configured to receive the second component the first data signal, and where the first differential circuit and the second differential circuit jointly generates a differential output signal at the differential output port.

In some implementations, the switch of each driver circuit comprises a transistor having a gate terminal configured to receive the control signal.

In some implementations, the integrated circuit includes a control circuit configured to operate each driver circuit in one of a plurality of operation modes.

In some implementations, the control circuit includes a mode selection port configured to receive mode selection signals for the plurality of driver circuits.

In some implementations, the control circuit is configured to assign a plurality of weights to each concurrently selected mode for the plurality of driver circuits, respectively.

In some implementations, the multiple weights are determined based on unit weighting, binary weighting, or a combination of unit weighting and binary weighting.

In some implementations, the data signal sources comprise corresponding shift registers configured to convert an input signal to a sequential multi-tap input signal, and wherein the control circuit is configured to provide the sequential multi-tap input signal to the plurality of driver circuits.

In some implementations, the first differential circuit comprises a plurality of thin oxide transistors, and the second differential circuit comprises a plurality of thick oxide transistors.

The details of one or more implementations are set forth in the accompanying drawings and the description below. Other aspects, features, and advantages will become apparent from the description, the drawings, and the claims.

### BRIEF DESCRIPTION OF DRAWINGS

FIG. 1 illustrates an example of a differential line driver segment, according to some implementations.

FIG. 2 illustrates an example table showing different operating modes of driver elements of a differential line driver segment, according to some implementations.

FIG. 3 illustrates an example of a differential line driver segment under the control of a control circuit, according to some implementations.

Like reference symbols in the various drawings indicate like elements.

### DETAILED DESCRIPTION

Traditional voltage mode drivers and current mode drivers have advantages and shortcomings. Efforts thus far to combine voltage modulation and current modulation are functionally effective but may result in compromised performance and power and/or area efficiency. A number of hybrid differential line driver ICs predominantly combine global voltage mode output scaling with programmable current mode modulation. In contrast, being able to combine programmable linear modulation of a voltage mode driver with global amplitude scaling of a current mode driver can be desirable. To retain the flexibility for handling the needs of various applications, the ability to configure output common mode voltage and output impedance is desirable as well.

Moreover, to accommodate the pullup voltage headroom for current mode operation without significantly reducing power efficiency, it is further desirable to supply the voltage mode driver with a lower supply voltage Vdd while separately supplying the amplitude scaler current with a higher voltage VddH, the latter current expended only when configured to do so. Having pullup-only current mode hybridization can avoid the pulldown voltage headroom issues imposed by existing push-pull current source approaches due to the lack of supply sources below Vss (the negative supply voltage or the ground supply voltage) in the driver circuit. Having separate Vdd and VddH can also improve high-speed operation reliability and performance because Vdd-to-VddH level shifters are not needed.

Furthermore, a voltage mode driver may include one or more thin oxide transistors. When scaling the amplitude in the current mode, it is imperative to prevent these thin oxide transistors from being overdriven by an out-of-range voltage. Such overstress can happen during pathological scenarios, such as hot-unplug system events when external loads are instantaneously withdrawn during normal transmission.

Considering the above challenges, this disclosure provides a design of a differential line driver segment. As described in detail below, one or more implementations of the present disclosure provides a modular/array-based segmented differential line driver that includes a pullup-only current-mode driver portion powered by a higher voltage VddH to, on demand, scale up the amplitude of a push-pull voltage-mode driver portion powered by a lower voltage Vdd. The combination of the pullup-only current-mode driver portion and the push-pull voltage-mode driver portion allows preservation of the linear operation of voltage-mode transmitter feed forward equalization (FFE), voltage-mode transmitter amplitude control, and voltage-mode transmitter output impedance, without requiring level-shifters in pre-drivers and avoiding over-voltaging thin oxide transistors (e.g., applying excess voltage to the thin oxide transistors). Compared with existing techniques, implementations of the present disclosure can advantageously address some or all issues described above.

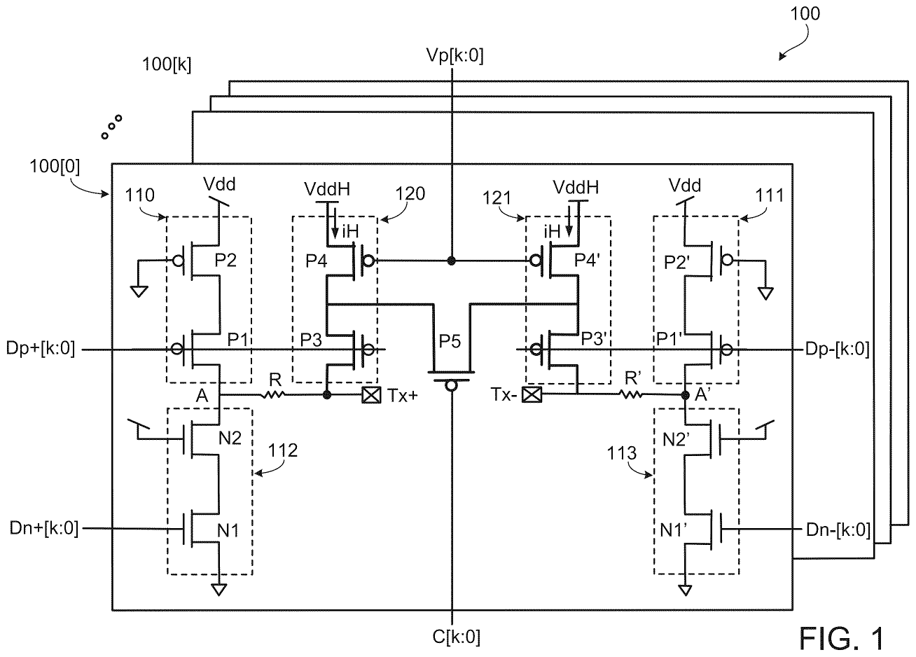

FIG. 1 illustrates an example of a differential line driver segment 100, according to some implementations. As illustrated, segment 100 includes an array of (k+1) driver elements 100[0] to 100[k], with k being 0 or greater.

All of driver elements 100[0] to 100[k] are supplied with a first voltage supply configured to provide a first voltage rail Vdd and a second voltage supply configured to provide a second voltage rail VddH. Voltage rails Vdd and VddH can supply power to a push-pull voltage-mode driver circuit and a pullup-only current-mode driver circuit, respectively. VddH can be higher than Vdd. All of driver elements 100[0] to 100[k] can share the same ground voltage Vss.

Segment 100 is configured to receive a first data signal (Dp+[k:0], Dp−[k:0]) and a second data signal (Dn+[k:0], Dn−[k:0]), which can represent digital input data having (k+1) bits. In some examples, the first data signal and the second data signal can each be complementary data signals. Each bit of the first data signal is input to a corresponding driver element. Similarly, each bit of the second data signal is input to a corresponding driver element. For example, driver element 100[0] is configured to receive (Dp+[0], Dp−[0]) and (Dn+[0], Dn−[0]), driver element 100[1] is configured to receive (Dp+[1], Dp−[1]) and (Dn+[1], Dn−[1]), and so forth. Each bit of data signals (Dp+[k:0], Dp−[k:0]) and (Dn+[k:0], Dn−[k:0]) can be either logic 1, represented by a voltage substantially equal to Vdd, or logic 0, represented by a voltage substantially equal to Vss.

Segment 100 is configured to receive a bias voltage signal Vp[k:0] and a control signal C[k:0]. Bias voltage signal Vp[k:0] can be an analog signal having (k+1) instances while control signal C[k:0] can be a digital signal having (k+1) bits. Each instance of the bias voltage signal is input to a corresponding driver element, and each bit of the control signal is input to a corresponding driver element. For example, driver element 100[0] is configured to receive Vp[0] and C[0], driver element 100[1] is configured to receive Vp[1] and C[1], and so forth.

Based on the input signals and the voltage supplies, each of driver elements 100[0] to 100[k] is configured to generate a differential output signal. The differential output signals generated by all of driver elements 100[0] to 100[k] are linearly superposed on differential output port (Tx+, Tx−). For example, in some implementations, the differential output signal output by each driver element 100[i] (i=0, 1, . . . k) is assigned a weight, which may or may not equal the weights assigned to other differential output signals. The superposition of differential output signals on differential output port (Tx+, Tx−) thus equals the weighted sum of the amplitudes of all differential output signals multiplied by their respective weights.

The (k+1) driver elements can have identical or similar circuit structures. As described above, each driver element has a push-pull voltage-mode driver circuit and a pullup-only current-mode driver circuit. Using driver element 100[0] as an example, the push-pull voltage-mode driver circuit is a differential circuit that has two portions respectively receiving data input signals. As illustrated, a first portion includes pull-up circuit 110 and pull-down circuit 112, which are coupled to each other at node A and together form a push-pull circuit. Likewise, a second portion includes pull-up circuit 111 and pull-down circuit 113, which are coupled to each other at node A′ and form another push-pull circuit. The two push-pull circuits together form a differential push-pull voltage-mode driver circuit. In addition, the pullup-only current-mode driver circuit includes first pull-up portion 120 and second pull-up portion 121, which together form a differential pullup-only current-mode driver circuit.

The differential push-pull voltage-mode driver circuit and the differential pullup-only current-mode driver circuit are jointly coupled to differential output port (Tx+, Tx−). For example, the differential push-pull voltage-mode driver circuit formed by circuits 110-113 can be coupled to differential output port (Tx+, Tx−) via resistors R and R′, whereas the differential pullup-only current-mode driver circuit formed by portions 120 and 121 can be coupled to differential output port (Tx+, Tx−) without intervening resistors.

Pull-up circuits 110 and 111 each include at least one pull-up transistor. In the illustrated implementations, pull-up circuit 110 includes a stack of p-type metal-oxide-semiconductor (PMOS) transistors P2 and P1, whereas pull-up circuit 111 includes a stack of PMOS transistors P2′ and P1′. Similarly, pull-down circuits 112 and 113 each include at least one pull-down transistor. In the illustrated implementations, pull-down circuit 111 includes a stack of n-type metal-oxide-semiconductor (NMOS) transistors N2 and N1, whereas pull-down circuit 113 includes a stack of NMOS transistors N2′ and N1′. In other implementations, the number of transistors in each of pull-up circuits 110 and 111 and/or in each of pull-down circuits 112 and 113 can be higher or lower. For example, in some implementations, P2 and P2′ can be omitted from pull-up circuits 110 and 111, leaving one transistor in each pull-up circuit. Similarly, in some implementations, N2 and N2′ can be omitted from pull-down circuits 112 and 113, leaving one transistor in each pull-down circuit.

In pull-up circuit 110, the source terminal of P2 is coupled to Vdd, and the gate terminal of P2 is grounded. The source terminal of P1 is coupled to the drain terminal of P2, and the gate terminal of P1 is configured to receive a corresponding bit Dp+[0] of first input signal Dp+[k:0]. The drain terminal of P1 is coupled to resistor R at node A. Pull-up circuit 111 can have a similar circuit structure, with the gate terminal of P1′ configured to receive a corresponding bit Dp−[0] of first input signal Dp−[k:0] and with the drain terminal of P1 coupled to resistor R′ at node A′.

In pull-up circuits 110 and 111, transistors P2 and P2′, whose gate terminals are grounded, are configured to be always ON and improves circuits' reliability by improving electrostatic discharge (ESD) immunity. As described above, some implementations can have more transistors in addition to P2 and P2′ to further improve circuit reliability, while some implementations can have P2 and P2′ omitted.

In some implementations, the relative positions of transistors P2 and P1 can be interchanged, whereby the newly situated P2's gate terminal may be cascoded to a non-grounded voltage. With the change, P1 can have its source terminal coupled to Vdd and its drain terminal coupled to the source terminal of P2, and P2 can have its drain terminal coupled to node A. In implementations where additional transistors are included in the stack to improve circuit reliability, the relative positions of transistors in the PMOS stack can be varied accordingly. The arrangement of the PMOS stack of pull-up circuit 110 can be similarly applied to pull-up circuit 111.

In pull-down circuit 112, the source terminal of N1 is grounded, and the gate terminal of N1 is configured to receive a corresponding bit Dn+[0] of second input signal Dn+[k:0]. The source terminal of N2 is coupled to the drain terminal of N1, and the gate terminal of N2 is coupled to Vdd. The drain terminal of N2 is coupled to resistor R at node A. Pull-down circuit 113 can have a similar circuit structure, with the gate terminal of N1′ configured to receive a corresponding bit Dn−[0] of second input signal Dp−[k:0] and with the drain terminal of N2′ coupled to resistor R′ at node A′.

In pull-down circuits 112 and 113, transistors N2 and N2′, whose gate terminals are coupled to Vdd, are configured to be always ON and improves circuits' reliability by providing overvoltage protection. As described above, some implementations can have more transistors in addition to N2 and N2′ to further improve circuit reliability, while some implementations can have N2 and N2′ omitted.

Pull-up portions 120 and 121 have PMOS transistors P4 and P4′, respectively. The source terminals of P4 and P4′ are coupled to VddH and the gate terminals of P4 and P4′ are configured to receive bias voltage signal Vp[0], which is the instance of bias voltage signal Vp[k:0] corresponding to driver element 100[0]. Vp[0] can be set such that P4 and P4′ both operate in the saturation region. In this case, P4 and P4′ each function as a current source that outputs a constant current. The value of the output currents is scalable based on the value of Vp[0]. For example, Vp[0] can be set such that the output currents are within a range of 0 to iH, where iH denotes a bias current value that is predetermined.

Pull-up portions 120 and 121 also have PMOS transistors P3 and P3′, respectively. The source terminals of P3 and P3′ are coupled to the drain terminals of P4 and P4, respectively, and the drain terminals of P3 and P3′ are coupled to differential output port (Tx+, Tx−).

The source terminals of P3 and P3′ are coupled to each other by a switch that is controlled by control signal C[0]. Control signal C[0] can be a binary digital signal. In the illustrated implementations, the switch includes PMOS transistor P5 whose gate terminal is controlled by control signal C[0]. When C[0] equals logic 0, P5 is activated to allow currents flow between the source terminals of P3 and P3′. When C[0] equals logic 1, P5 is deactivated such that no currents flow between the source terminals of P3 and P3′. Other implementations can use different circuit components to implement the switch between P3 and P3′.

The gate terminals of P3 and P3′ are configured to receive Dp+[0] and Dp−[0], respectively. This way, the pair of bits (Dp+[0], Dp−[0]) from first data signal (Dp+[k:0], Dp−[k:0]) are provided both to the push-pull voltage-mode driver circuit and to the pullup-only current-mode driver circuit, without potential penalty of level shifter delay or signal distortion

In the push-pull voltage-mode driver circuit of driver element 100[0], transistors P1, P2, P1′, P2′, N1, N2, N1′, and N2′, which operate based on the power supply of Vdd, can be implemented with thin oxide transistors. Meanwhile, in the pullup-only current-mode driver circuit of driver element 100[0], transistors P3, P4, P3′, and P4′, which operate based on the power supply of VddH, can be implemented with thick oxide transistors. Compared to thick oxide transistors, thick oxide transistors typically can withstand higher voltages without breaking down but occupy more circuit area. Although the terms “thick” and “thin” are relative, the thicknesses of thick and thin oxide transistors are usually readily ascertainable depending on the fabrication process of an IC. The thickness of the oxide layer influences the electrical properties of the transistors, including threshold voltage, drive current, and leakage current. The thicker oxide layer may facilitate achieving higher voltage tolerance and reliability in these circuits. In some implementations, a thick oxide transistor can be replaced by multiple thin oxide transistors, and/or thin oxide transistor(s) operating in a cascoded topology whose corresponding gate terminals are biased with a cascode voltage

Thin oxide transistors P1, P2, P1′, P2′, N1, N2, N1′, and N2′ are configured (e.g., manufactured with physical characteristics) to operate in the Vdd domain. This means these transistors treat a voltage of Vdd as logic 1.

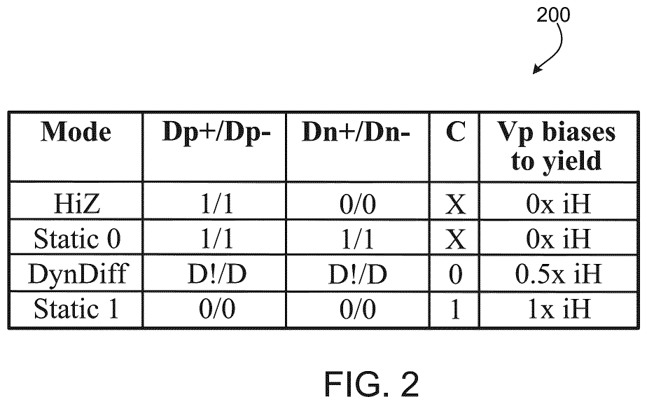

Depending on the input signals, each driver element of segment 100 can operate in one of a plurality of modes. These modes are described below with reference to FIG. 2, again using driver element 100[0] as an example.

FIG. 2 illustrates an example table 200 showing different operating modes of driver elements of a differential line driver IC, according to some implementations. Table 200 shows four modes: a) HiZ (also known as high impedance) mode; b) Static 0 (or Static_0) mode; c) dynamic differential (DynDiff) mode; and d) Static 1 (or Static_1) mode. Each mode corresponds to a set of input signal values, as described in detail below.

### HiZ Mode

In the HiZ mode, both components of the first data signal (Dp+[k:0], Dp−[k:0]) are set to logic 1 (which corresponds to a voltage of Vdd), and both components of the second data signal (Dn+[k:0], Dn−[k:0]) are set to logic 0 (which corresponds to a voltage of Vss), and as such, the D+ and D− pairs are thus not complementary in this mode. Accordingly, driver element 100[0] is configured to receive as inputs (Dp+[0], Dp−[0])=(1, 1) and (Dn+[0], Dn−[0])=(0, 0). As a result, transistors P1, P1′, N1, and N1′, which operate in the Vdd domain, are all deactivated.

Also, the logic value of control signal C[k:0] is “don't care,” denoted as X, which means either logic 1 or logic 0. Accordingly, driver element 100[0] is configured to receive C[0]=1 or C[0]=0.

Further, bias voltage signal Vp[k:0] is set such that the current sources in the pullup-only current-mode driver circuit are shut off. For example, to shut off the current sources in driver element 100[0], Vp[0] can be set such that Vp[0]≥VddH−|Vtp_thick|, where Vtp_thick is the threshold voltage of P4 and P4′ (which are thick oxide PMOS transistors) at the given manufacturing process and operating temperature. As a result, there is substantially no current (0×iH) flowing from transistors P4 and P4′ to transistors P3 and P3′, respectively, in driver element 100[0].

The pair (Dp+[k:0], Dp−[k:0]) are also respectively input to the gate terminals of P3 and P3′. This makes the gate voltages of thick oxide transistors P3 and P3′ equal to the gate voltages of thin oxide transistors P1 and P1′, Vdd. Despite the voltage at the gate terminals of P3 and P3′, because no current flows over transistors P4 and P4′ (and consequently no current flows over transistors P3 and P3′), P3 and P3′ each see a source voltage that is less than or equal to Vdd+|Vtp_thick|. This way, P3 and P3′ can be deactivated even if their respective gate voltages (i.e., Vdd) are less than the voltage corresponding to logic 1 (i.e., VddH for P3 and P3′). Compared to existing techniques, P3 and P3′ can be conveniently deactivated without the need of a voltage level shifter that converts Vdd to VddH to feed to the gate terminals of P3 and P3′.

In addition, because Vdd domain transistors P1, P1′, N1, and N1′, and VddH domain transistors P3 and P3′, are all deactivated, there is no current path between Tx+ and Tx−, and there is no current path from Vdd, VddH, or ground (e.g., Vss) to Tx+ and Tx−. As such, regardless of the state of P5, Tx+ and Tx− are at the high impedance state.

### Static 0 Mode

In the Static 0 mode, both components of the first data signal (Dp+[k:0], Dp−[k:0]) are set to logic 1, and both components of the second data signal (Dn+[k:0], Dn−[k:0]) are set to logic 1, and as such, the D+ and D− pairs are thus not complementary in this mode. Accordingly, driver element 100[0] is configured to receive as inputs (Dp+[0], Dp−[0])=(1, 1) and (Dn+[0], Dn−)=(1, 1). As a result, transistors P1 and P1′ are deactivated while transistors N1 and N1′ are activated.

Also, the logic value of control signal C[k:0] is “don't care.” Accordingly, driver element 100[0] is configured to receive C[0]=1 or C[0]=0. Further, bias voltage signal Vp[k:0] is set such that the current sources P4 and P4′ in the pullup-only current-mode driver circuit are shut off. Vp[k:0] can have an analog bias voltage. As a result, there is substantially no current (0×iH) flowing from transistors P4 and P4′ to transistors P3 and P3′, respectively, in driver element 100[0].

Similar to the HiZ mode, transistors P1, P1′, P3, and P3′ are all deactivated, which means no current path between Tx+ and Tx− (regardless of whether P5 is activated), and no current path from Vdd or VddH to Tx+ and Tx−. However, transistors N1 and N1′ are activated, thereby providing isolated current paths between Tx+ and Tx− and the ground (e.g., Vss), through resistors R and R′, respectively. As such, each of Tx+ and Tx− can be considered statically pulled down to a Thevenin equivalent voltage of Vss, or static 0. The Thevenin equivalent output impedance seen on Tx+ (or likewise Tx−) is the series resistance of N1 (or N1′ for Tx−), N2 (or N2′ for Tx−), and R (or R′ for Tx−) combined.

### DynDiff Mode

DynDiff is the mode in which each driver element dynamically receives a bit of input data D and a logic complement of the input data D!. In this case, the DynDiff mode is the only mode among the multiple modes that utilizes complementary signaling. According to table 200, when the bit of input data D corresponding to driver element 100[0] is logic 0, the corresponding bits of first complementary signal (Dp+[0], Dp−[0]) and second complementary signal (Dn+[0], Dn−[0]) are both (D!, D)=(1, 0). Conversely, when the bit of input data D corresponding to driver element 100[0] is logic 1, the corresponding bits of first complementary signal (Dp+[0], Dp−[0]) and second complementary signal (Dn+[0], Dn−[0]) are both (D!, D)=(0, 1). Since D is not exclusively defined as logic 0 or logic 1, the inverse of the foregoing example can also apply in some embodiments.

Also, the logic value of control signal C[k:0] is logic 0. Accordingly, driver element 100[0] is configured to receive C[0]=0, thereby activating transistor P5 to create a current path between the respective source terminals of transistors P3 and P3′.

Further, bias voltage signal Vp[k:0] is set such that the current sources in the pullup-only current-mode driver circuit each output a current with an amplitude equal to 0.5 times iH (0.5×iH) flowing to transistors P3 and P3′.

With the input data bit changing dynamically between 0 and 1, the statuses of Vdd domain transistors P1, P1′, N1, and N1′ also change dynamically. Specifically, when the input data bit D=0, P1 and N1′ are deactivated while P1′ and N1 are activated. Conversely, when the input data bit D=1, P1 and N1′ are activated while P1′ and N1 are deactivated.

Meanwhile, the activation of P5 allows the currents output by current sources P4 and P4′ and flowing through P3 and P3′ to be combined, resulting a current with an amplitude equal to (0.5+0.5) times iH, or 1×iH. At the same time, the gate voltages of P3 and P3′ are same as those of P1 and P1′, respectively, which can be either Vdd or Vss, depending on the input data bit D.

By virtue of the aforementioned combined tail nodes (i.e. combing the currents output by current sources P4 and P4′), P3 and P3′ function as an analog differential pair, dynamically steering current towards Tx− if D=0 or towards Tx+ if D=1, without requiring a Vdd-to-VddH level shifter. Such current steering behaves as a limiting output amplifier rather than a linear output amplifier. Moreover, when D=0, N1′ is deactivated, so the current towards Tx− does not have path to Vss. Similarly, when D=1, N1 is deactivated, so the current towards Tx+ does not have path to Vss. As such, symmetric analog current steering from fixed current sources is demonstrably only from VddH, and because of the absence of symmetric analog current steering towards Vss, problems with respect to pulldown voltage headroom or the need for return path voltages below Vss can be avoided.

Accordingly, driver element 100[0], when operating in the DynDiff mode, functions as an inverting driver with dynamic inputs D! /D and outputs Tx+/Tx−. The Thevenin equivalent voltage is Vss when pulling down. When pulling up, however, there are current branches. The VddH current iH travels through ports Tx+ and Tx− and resistors R and R′ back to Vdd, while branching from ports Tx+ and Tx− through the external differential signal channel (e.g., signal channel coupled to the driver circuit) to external termination (generally AC-coupled). The pullup Thevenin equivalent voltage is thus higher than Vdd with a non-zero iH.

Consequently, without affecting the voltage mode pulldown structure, the effective output amplitude (both differential and common mode) is scaled up as a function of iH and load impedance. The Thevenin equivalent output impedance as seen on Tx+ (or likewise Tx−) is the series resistance of N1 (or N1′ for Tx−), N2 (or N2′ for Tx−), and R (or R′ for Tx−) when pulling down, or P1 (or P1′ for Tx−), P2 (or P2′ for Tx−), and R (or R′ for Tx−) when pulling up. This output impedance is unaffected by the iH current path so long as P4 and P4′ are kept in PMOS saturation (i.e., as current sources), and the scaled Tx+ and Tx− voltages do not exceed Vdd+|Vtp_thin|, where Vtp_thin is the threshold voltage of P1 and P1′.

### Static 1 Mode

In the Static 1 mode, both components of the first data signal (Dp+[k:0], Dp−[k:0]) are set to logic 0, and both components of the second complementary signal (Dn+[k:0], Dn−[k:0]) are set to logic 0, and as such, the D+ and D− pairs are thus not complementary in this mode. Accordingly, driver element 100[0] is configured to receive as inputs (Dp+[0], Dp−[0])=(0, 0) and (Dn+[0], Dn−[0])=(0, 0). As a result, transistors P1 and P1′ are activated while transistors N1 and N1′ are deactivated.

Moreover, the logic value of control signal C[k:0] is set as logic 1. Accordingly, driver element 100[0] is configured to receive C[0]=1, thereby deactivating transistor P5 and isolating the tail nodes from each of current sources P4 and P4′. Further, bias voltage signal Vp[k:0] is set such that the current sources P4 and P4′ in the pullup-only current-mode driver circuit each output a current with an amplitude equal to iH, twice that of the output current in the DynDiff mode. The currents flow through transistors P3 and P3′, whose gate voltages are Vss, the same as those of transistors P1 and P1′, simultaneously pulling the common source terminals of P3, P3′ and P5 below Vdd, helping to render P5 inactive when C[0]=1. Unlike the DynDiff mode, transistors P3 and P3′ do not act as a differential pair in the Static 1 mode because both Tx+ and Tx− are pulled up by transistors P3 and P3′.

In the Static 1 mode, the deactivation of P5 results in no current path between ports Tx+and Tx−. Meanwhile, there are isolated current paths from Vdd to ports Tx+ and Tx− through resistors R and R′, respectively. There are also isolated current paths from VddH to P3 and P3′ because of the currents output by current sources P4 and P4′, respectively. Also, the deactivation of N1 and N1′ results in no current path from ports Tx+ and Tx− to Vss. Accordingly, each of ports Tx+ and Tx− can be considered to be statically pulled up to static 1.

In the Static 1 mode, the output currents from current sources P4 and P4′ travels from Tx+ and Tx− through R and R′, respectively, to Vdd. The currents also branch from ports Tx+ and Tx− through the external differential signal channel to the external termination. Compared to circuits with only a voltage mode driver, the effective output signal level of driver element 100[0] is scaled up as a function of iH and the load impedance.

The Thevenin equivalent output impedance as seen on ports Tx+ (or likewise Tx−) is the series resistance of P1 (or P1′ for Tx−), P2 (or P2′ for Tx−), and R (or R′ for Tx−) on the path that terminates at Vdd. This output impedance is unaffected by the iH current path through P3 and P4 (or P3′ and P4′ for Tx−) so long as P4 and P4′ are kept in PMOS saturation, and the scaled Tx+ and Tx− voltages do not exceed Vdd+|Vtp_thin|.

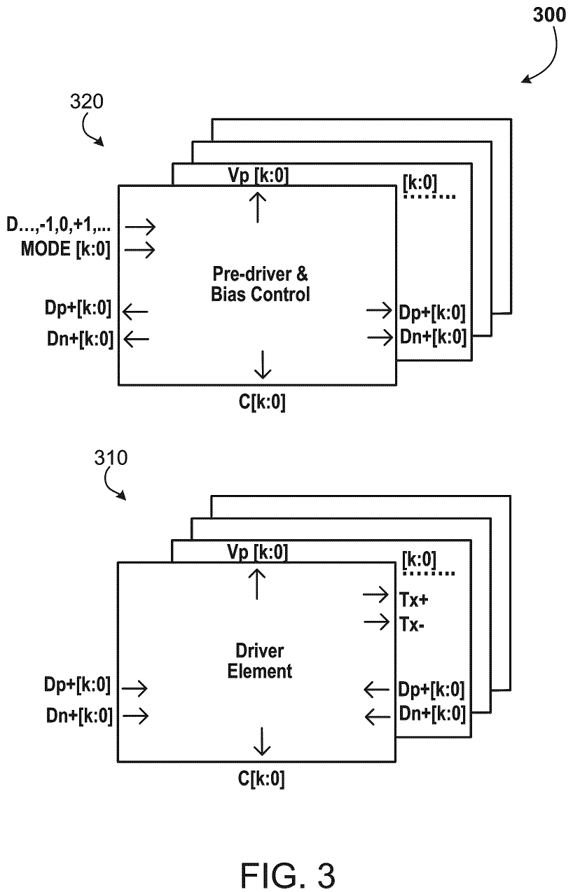

FIG. 3 illustrates an example of differential line driver segment 310 under the control of control circuit 320, according to some implementations. Segment 310 and control circuit 320 together form segment 300.

Segment 310 can be similar to segment 100 of FIG. 1 and can include an array of (k+1) driver elements, referred to as driver elements 310[0] to 310[k]. All driver elements of IC 310 can share the same voltage rails Vdd and VddH as well as the ground voltage Vss. These voltage supplies are omitted in FIG. 3 for brevity.

Correspondingly, control circuit 320 includes an array of (k+1) control circuit elements, referred to as control circuit elements 320[0] to 320[k]. Control circuit elements 320[0] to 320[k] can have identical or similar circuit structures. The below descriptions use control circuit element 320[0] as an example to show the control of driver element 310[0].

Control circuit element 320[0] includes a pre-driver circuit and bias control circuit, which can be physically integrated on a single piece of hardware or separated on different pieces of hardware. The pre-driver circuit operates in the Vdd domain and is configured to generate the input signals, such as first and second data signals (Dp+[0], Dp−[0]) and (Dn+[0], Dn−[0]) and control signal C[0], of driver element 310[0]. The bias control circuit is configured to generate bias voltage signal Vp[0] using VddH as a reference voltage so as to control the current sources of driver element 310[0] (similar to current sources P4 and P4′ in FIG. 1) and scale the output current iH.

Control circuit element 320[0] has a mode selection port that receives a mode selection signal Mode[0], which can be a multi-bit signal indicating one of the modes illustrated in FIG. 2. The mode selection signals for the array of (k+1) control circuit elements thus form mode selection signal Mode[k:0], which has (k+1) instances of multi-bit mode selection signal, Mode[0], Mode[1], . . . Mode [k]. Control circuit 320 can receive mode[k:0] from, e.g., a register in a configuration logic block, a microcontroller, or a state machine circuit.

Control circuit element 320[0] also receives a bit of input data D and converts input data D to first and second data signals (Dp+[0], Dp−[0]) and (Dn+[0], Dn−[0]), depending on the mode selection. As described above, control circuit element 320[0] is configured to set (Dp+[0], Dp−[0]) and (Dn+[0], Dn−[0]) both to (D!, D) when driver element 310[0] is configured to operate in the DynDiff mode. When driver element 310[0] is configured to operate in the HiZ mode, the Static 0 mode, or the Static 1 mode, control circuit element 320[0] is configured to set {(Dp+[0] or Dp−[0]) and (Dn+[0] or Dn−[0])} to {1, 0} or {1, 1} or {0, 0}respectively in accordance with table 200 of FIG. 2.

When segment 310 has an array of (k+1)>1 driver elements, which means control circuit 320 also has (k+1)>1 control circuit elements, input data D to each control circuit element can be denoted as D[0], D[1], . . . D[k]. In some implementations, D[0], D[1], . . . D[k] can be generated by multiplexing from a multi-tap data stream. For example, control circuit 320 can have a synchronous data shift register D . . . ,−1,0,+1 configured to feed a multi-tap input data stream to D[0], D[1], . . . D[k]. The multi-tap input data stream can include, e.g., (k+1) bits appearing on the same input data port at (k+1) consecutive clock cycles, respectively.

In segment 300, the [k:0] array of driver elements each driven by a control circuit element can be linearly weighted according to, e.g., a unit weighting mechanism, a binary weighting mechanism, or a mixture of binary and unit weighting.

For example, in the case of a binary weighting mechanism, if a 1× unit element of the [k:0] array of driver elements uses a particular number of driver shunt transistors and a particular number of shunt resistors, a corresponding 2× element can use twice the particular number of driver shunt transistors and twice the particular number of shunt resistors. Further, a corresponding 4× element can use quadruple the particular number of driver shunt transistors and quadruple the particular number of shunt resistors in order to form a binary weighted set of driver elements.

Alternatively, in the case of a unit weighting mechanism, if the 2× element is not formed by doubling the particular number of each device, the 2× element can instead be controlled separately as two sets of disjoint 1× elements. In this case, the mechanism allows for bifurcation of a 2× weight into 2 sets of 1× weights. That is, this bifurcation allows for independent weighting assignments for particular variables, such as impedance, amplitude, Tx equalization pre-shoot or equalization de-emphasis, output common mode voltage, or a combination thereof.

With the weighting, the outputs from the driver elements may have different impact on the superposition at output ports Tx+ and Tx−.

In general, a unit weighted implementation implies a larger k, and is generally suitable for systems requiring live mode reconfiguration, such as during mission mode when the impact of one potentially unsettled element configuration may be small compared to the sum of all unit weighted (k+1) elements. Individual units may be assigned to any functional mode and any input data tap. Larger weights of any amount may be formed by setting any number of available units to the same mode of configuration, and multiplexed to the same input data tap.

Alternatively, a binary weighted implementation implies a much smaller k, e.g., log2 as large, and is generally suitable for systems requiring non-live-traffic reconfiguration, such as during boot-up or during link training when the large impact of a binary weighted most significant bit (MSB) element may be tolerated by a given protocol due to an allowed settling or recovery time. To ensure that any number of elements is assignable to a given functional mode, multiple sets of binary weighted groups may be integrated. For instance, if each binary group has 2\hat{ }g−1 total weight, and g=5, and there exist 4 groups, then each binary weighted group has a total weight of 31, and 4 such groups have a total weight of 124. The 20 addressable binary weights can each be assigned to any functional mode of FIG. 2 and to any input data tap according to the needs of the driver application. The actual binary assignment may or may not be gray encoded.

A mixture of binary weighted and unit weights or groups of unit weights allow both dynamic “on-the-fly” adaptation and static configuration, while keeping the total addressable weights to a minimum. How many weights are assigned to each mode, and which data taps to assign to elements in the DynDiff mode, and the absolute value of iH, determine the output impedance, common mode voltage, voltage mode amplitude, transmitter FFE, and the scaling globally applied.

For each unit or binary weighted element in the array, the series resistor R's conductance (i.e., 1/R) and the transistor sizes may generally be scaled accordingly in some implementations. For instance, an 8× binary weighted element can have transistor conductance and resistor R conductance scaled by 8× vis-à-vis a 1× unit element. With multiple driver elements in parallel, the Thevenin equivalent output impedance of the total driver assembly is the shunt impedance of all the driver elements, regardless of the weighting scheme.

As the actual conductance may be a function of manufacturing process, supply and bias voltages, and semiconductor junction temperature (collectively referred to as PVT), a calibration subroutine may be employed in some implementations to determine the number of unit weights corresponding to a target output impedance. Once determined, the rest of the available elements connected to ports Tx+ and Tx− can be set to the HiZ mode to render these elements non-contributing to the output impedance. The active elements are left to be programmed to one of Static_0, Static_1, or DynDiff modes, whose weight assignments depend on the desired output amplitude, transmission FFE, and the output common mode voltage. For a given PVT corner, the output impedance is retained regardless of parametric updates to these modes so long as the calibrated number of unit weights remain unchanged. Moreover, as the voltage and/or the temperature vary in time, adaptive modification of said number of unit weights can maintain the output impedance under changing conditions. In some implementations, replica or representative copies of the transmitter (or portions thereof) may be employed in its adaptive control loop.

The Static_0 and Static_1 modes have versatile uses. As a driver element in the Static_0 and Static_1 modes is not affected by the input data stream, these modes may be utilized to configure the driver IC to an electrical idle state whose output common mode voltage is adjustable depending on the ratio of the number of driver elements in the Static_0 mode to the number of driver elements in the Static_1 mode. Static_0 and Static_1 modes may be used to terminate ports Tx+ and Tx− to Vss or Vdd or above Vdd when in combination with finite iH currents flowing from VddH. In conjunction with the DynDiff mode, the Static_0 and Static_1 modes may also be used to reduce the differential output amplitude of the driver IC depending on the ratio of the number of driver elements in the Static 0 or 1 modes versus the number of driver elements in the DynDiff mode. The output common mode voltage is adjustable as well depending on the ratio of driver elements in the Static_0 mode to the number of driver elements in the Static_1 mode.

In the Static_1 mode, the iH currents are double that of the 0.5 iH currents in DynDiff mode in order to maintain the common mode voltage Vcm when reconfiguring between the driver's mission mode (where differential data is transmitted at some common mode voltage Vcm) and electrical idle mode (where no differential data is transmitted but both wires of a differential channel are kept at the original Vcm). When transforming between the mission mode and the electrical idle of operation, Vcm is maintained by converting half the number of driver elements in DynDiff to Static_0, and converting the other half to Static_1, while also preserving the same output impedance.

One or more implementations can be configured with transmission equalization features. In the DynDiff mode, D! and D can hail from any transmission FFE tap (e.g., D−1 representing post-cursor data, D0! representing cursor data, D+1 representing pre-cursor data), and can extend to more taps or fewer taps represented by the generic notation D . . . ,−1,0,+1, . . . . Transmission FFE taps can be sourced from shift registers (e.g., D-flipflops with outputs and inputs successively configured in series), or any synchronously clocked state elements. Sufficient element weights can be allocated to each tap location to reach a targeted coefficient value range. The coefficient signs are dependent on the sense (e.g. negative for binary “0” while positive for binary “1”) of each corresponding tap's data D or D!. In particular, each coefficient represents a chosen total weight for each tap. For example, in the case where a tap number n has a coefficient of integer 6 and binary weighted, the element weight is a 4× element plus a 6× element both assigned to the tap n using the multiplexer. Importantly, the system can have a same number of sets of binary groups as the variables. In this way, the system does not exceed the binary elements needed to total the desired coefficient.

All driver elements in DynDiff, with various weights ascribed to D . . . ,−1,0,+1,. . . or D! . . . ,−1,0,+1, . . . , can be linearly superposed onto Tx+/Tx, implementing a sum-of-products function. Furthermore, amplitude scaling from the iH path linearly applies to each DynDiff component of Tx FFE, equivalent to global amplitude scaling, but without requiring a discrete linear analog output amplifier stage.

One or more implementations can be configured with thin oxide transistor overvoltage mitigation features. As discussed above, outputs of all driver elements are superposed on ports Tx+ and Tx−. Regardless of the modes of the driver elements, when a hot-unplug system scenario emerges during mission mode (e.g., when a line card is physically ejected from a chassis during link traffic), external termination may instantaneously disappear while the driver IC is still transmitting signals. Certain protocols may not immediately detect this condition and suspend data transmission, thereby creating a failsafe hazard to the unterminated driver IC. Depending on the data D, the current iH may cause either of Tx+ and Tx− to rise above Vdd. Referring to the example of segment 100, to prevent the drains of transistors N1 and N1′ from exceeding Vdd, transistors N2 and N2′ can be used with gates coupled to Vdd (e.g., through an intermediate tie-high cell to avoid a direct gate connection to supply). N2 and N2′ thus serve to limit said drain voltage in a pseudo-cascode NMOS topology.

One or more implementations can be configured with amplitude scaling features. The magnitude of current iH impacts the degree of amplitude assistance vis-a-vis the voltage mode driver alone. Setting iH=0 effectively yields no amplitude scaling. For subsequent scaling to a desired delta differential voltage as seen at ports Tx+ and Tx−, a corresponding delta iH may be biased by the bias control circuit, in consideration of the load channel impedance and termination resistance, and in consideration of the chosen transmitter output impedance. In some implementations, an open loop bias control scheme is employed, with predetermined incremental iH to achieve various amounts of scaling, with or without static or adaptive calibration. In some other implementations, an active bias feedback control mechanism is employed to continuously and dynamically produce the necessary iH current in order to achieve a target change in output differential amplitude. This can include employing a driver element replica structure in coordination with a delta-voltage reference source and an active amplifier servo control loop of the iH bias control circuit).

It will be understood that various modifications to the implementation describe above can be made without departing from the spirit and scope of the subject innovation. For instance, although the above descriptions are largely based on the four modes illustrated in FIG. 2, it is possible to configure a driver element to operate in alternative modes to realize the same functionality. In an example where the driver IC is configured to an electrical idle state, the control circuit can drive input data D=0 statically (which can be a special data setting) for a number of driver elements in the DynDiff mode while driving input data D=1 statically (which can be another special data setting) for the same number of driver elements also in the DynDiff mode. This configuration can be seen as an alternative to configurating said elements to Static 0 and Static 1.

Further, although the above descriptions with respect to driver elements of a driver IC are largely based on the circuitry shown in FIG. 1, it is possible to design a driver element based on alternative circuit implementations. As an example, although FIG. 1 shows a single PMOS transistor P5 used as a switch between pull-up portions 120 and 121, it is possible in some implementations to use other circuit components in addition to or in lieu of P5 to switch the current path between P3 and P3′ ON or OFF. In these implementations, control signal C[k:0] may correspondingly have values different from those shown in table 200 for DynDiff mode or Static 1 mode configurations.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

What is claimed is:

1. An integrated circuit, comprising:
a first voltage supply configured to provide a first voltage rail;
a second voltage supply configured to provide a second voltage rail higher than the first voltage rail;
a first differential circuit coupled to the first voltage supply and driven by the first voltage rail, the first differential circuit comprising a first push-pull portion and a second push-pull portion; and
a second differential circuit coupled to the second voltage supply and driven by the second voltage rail, the second differential circuit comprising a first pull-up portion and a second pull-up portion coupled to each other by a switch controlled by a control signal,
wherein the first push-pull portion is coupled to the first pull-up portion through a first resistor, and the second push-pull portion is coupled to the second pull-up portion through a second resistor,
wherein each of the first push-pull portion and the second push-pull portion comprises: a pull-up circuit coupled to the first voltage supply and configured to receive one of a first component and a second component of a first data signal; and a pull-down circuit coupled to a third voltage supply and configured to receive one of a first component and a second component of a second data signal,
wherein the first pull-up portion is configured to receive the first component of the first data signal, and the second pull-up portion is configured to receive the second component of the first data signal, and
wherein the first differential circuit and the second differential circuit jointly generate a differential output signal.

2. The integrated circuit of claim 1, wherein the pull-up circuit of the first push-pull portion and the pull-up circuit of the second push-pull portion each comprise at least one first p-type metal-oxide-semiconductor (PMOS) transistor of the pull-up circuit having a gate terminal configured to receive one component of the first data signal.

3. The integrated circuit of claim 2, wherein the pull-down circuit of the first push-pull portion and the pull-down circuit of the second push-pull portion each comprise at least one n-type metal-oxide-semiconductor (NMOS) transistor of the pull-down circuit configured to receive one component of the second data signal.

4. The integrated circuit of claim 1, wherein the first pull-up portion and the second pull-up portion each comprise a first PMOS transistor of the pull-up portion, and a second PMOS transistor of the pull-up portion, wherein a gate terminal of the first PMOS transistor of the first pull-up portion and a gate terminal of the first PMOS transistor of the second pull-up portion are both coupled to a bias voltage to form one or more current sources.

5. The integrated circuit of claim 4, wherein the first pull-up portion and the second pull-up portion each comprise a second PMOS transistor, wherein a gate terminal of the second PMOS transistor of the first pull-up portion and a gate terminal of the second PMOS transistor of the second pull-up portion are respectively coupled to one of the first and second components of the first data signal.

6. The integrated circuit of claim 5, wherein a drain terminal of the second PMOS transistor of the first pull-up portion and a drain terminal of the second PMOS transistor of the second pull-up portion are jointly coupled to a differential output port that outputs the differential output signal.

7. The integrated circuit of claim 2, wherein the at least one first PMOS transistor comprises a plurality of first PMOS transistors having a gate terminal coupled to the third voltage supply.

8. The integrated circuit of claim 3, wherein the at least one NMOS transistor comprises a plurality of NMOS transistors having a gate terminal that is coupled to the first voltage supply.

9. The integrated circuit of claim 1, wherein the switch comprises a transistor having a gate terminal configured to receive the control signal.

10. The integrated circuit of claim 1, wherein the integrated circuit is configured to operate in one of: a first mode, a second mode, a third mode, and a fourth mode;
wherein when the integrated circuit operates in the first mode, the integrated circuit converts the first and the second components of the first data signal both to logic 1, converts the first and the second components of the second data signal both to logic 0, and sets an incremental current to zero to turn off amplitude scaling;
wherein when the integrated circuit operates in the second mode, the integrated circuit converts the first and the second components of the first data signal both to logic 1, converts the first and the second components of the second data signal both to logic 1, and sets the incremental current to zero to turn off amplitude scaling;
wherein when the integrated circuit operates in the third mode, the integrated circuit converts the first components of the first and second data signals to first digital counterparts, converts the second components of the first and second data signals to second digital counterparts, sets the control signal to logic 0, and sets an incremental current at 0.5 times a bias current to turn on amplitude scaling, wherein the second digital counterparts are complements of the first digital counterparts; and
wherein when the integrated circuit operates in the fourth mode, the integrated circuit converts the first and the second components of the first data signal both to logic 0, converts the first and the second components of the second data signal both to logic 0, sets the control signal to logic 1, and sets the incremental current to equal the bias current to turn on amplitude scaling.

11. The integrated circuit of claim 10, wherein the incremental current is adjusted according to an incremental differential voltage of the differential output signal.

12. The integrated circuit of claim 1, wherein the first differential circuit comprises a plurality of thin oxide transistors, and the second differential circuit comprises a plurality of thick oxide transistors.

13. An integrated circuit, comprising:
a plurality of driver circuits;
a first voltage supply configured to provide a first voltage rail;
a second voltage supply configured to provide a second voltage rail higher than the first voltage rail;
a differential output port coupled to the plurality of driver circuits;
a control port configured to provide a plurality of control signals to the plurality of driver circuits, respectively;
a first differential input port configured to provide a plurality of first differential input signals to the plurality of driver circuits, respectively;
a second differential input port configured to provide a plurality of second differential input signals to the plurality of driver circuits, respectively;
wherein each driver circuit of the plurality of driver circuits comprises:
a first differential circuit coupled to the first voltage supply and driven by the first voltage rail, the first differential circuit comprising a first push-pull portion and a second push-pull portion; and
a second differential circuit coupled to the second voltage supply and driven by the second voltage rail, the second differential circuit comprising a first pull-up portion and a second pull-up portion coupled to each other by a switch controlled by a control signal,
wherein the first push-pull portion is coupled to the first pull-up portion through a first resistor, and the second push-pull portion is coupled to the second pull-up portion through a second resistor,
wherein each of the first push-pull portion and the second push-pull portion comprises: a pull-up circuit coupled to the first voltage supply and configured to receive one of a first component and a second component of a first data signal; and a pull-down circuit coupled a third voltage supply and configured to receive one of a first component and a second component of a second data signal,
wherein the first pull-up portion is configured to receive the first component of the first data signal, and the second pull-up portion is configured to receive the second component the first data signal, and
wherein the first differential circuit and the second differential circuit jointly generates a differential output signal at the differential output port.

14. The integrated circuit of claim 13,
wherein the switch of each driver circuit comprises a transistor having a gate terminal configured to receive the control signal.

15. The integrated circuit of claim 13, further comprising a control circuit configured to operate each driver circuit in one of a plurality of operation modes.

16. The integrated circuit of claim 15, wherein the control circuit comprises a mode selection port configured to receive mode selection signals for the plurality of driver circuits.

17. The integrated circuit of claim 15, wherein the control circuit is configured to assign a plurality of weights to each concurrently selected mode for the plurality of driver circuits, respectively.

18. The integrated circuit of claim 17, wherein the plurality of weights are determined based on unit weighting, binary weighting, or a combination of unit weighting and binary weighting.

19. The integrated circuit of claim 15, wherein sources of the data signals comprise corresponding shift registers configured to convert an input signal to a sequential multi-tap input signal, and wherein the control circuit is configured to provide the sequential multi-tap input signal to the plurality of driver circuits.

20. The integrated circuit of claim 13, wherein the first differential circuit comprises a plurality of thin oxide transistors, and the second differential circuit comprises a plurality of thick oxide transistors.
